(19) United States
(12) Patent Application Publication
(10) Pub. No.: US 2016/0309596 A1
(43) Pub. Date: Oct. 20, 2016

(54) METHODS FOR FORMING COBALT INTERCONNECTS

(71) Applicant: APPLIED Materials, Inc., Santa Clara, CA (US)

(72) Inventors: Roey Shaviv, Palo Alto, CA (US); John W. Lam, San Jose, CA (US); Timothy Bochman, Kalispell, MT (US); Jennifer Meng Chu Tseng, Saratoga, CA (US)

(21) Appl. No.: 14/687,755

(22) Filed: Apr. 15, 2015

(51) Int. Cl. H05K 3/18; C25D 5/34; C21D 1/26; C25D 3/12; C22F 1/10; C21D 9/00; C25D 7/12; C25D 5/50

(52) U.S. Cl. CPC H05K 3/181; C25D 7/123; C25D 5/34; C25D 5/50; C25D 3/12; C22F 1/10; C21D 9/0062; C21D 1/26; H05K 3/188

(57) ABSTRACT

A method for depositing metal in a feature on a workpiece includes forming a seed layer in a feature on a workpiece, wherein the seed layer includes a metal selected from the group consisting of cobalt and nickel; electrochemically depositing a first metallization layer on the seed layer, wherein electrochemically depositing the metallization layer includes using a plating electrolyte having a plating metal ion and a pH in the range of 6 to 13; and heat treating the workpiece after deposition of the first metallization layer.

### BACKGROUND

The present disclosure relates to producing interconnects in semiconductor devices. Integrated circuits (IC) include various semiconductor devices formed within or on layers of dielectric material that overlay a substrate. Such devices which may be formed in or on the dielectric layers include MRS transistors, bipolar transistors, diodes, and diffused resistors. Other devices which may be formed in or on the dielectric material include thin film resistors and capacitors. Metal lines interconnect the semiconductor devices to power such devices and enable such devices to share and exchange information. Such interconnects extend horizontally between devices within a dielectric layer as well as vertically between dielectric layers. These metal lines are connected to each other by a series of interconnects. The electrical interconnects or metal lines are first patterned into the dielectric layers to form vertical and horizontal recessed features (vias and trenches) that are subsequently filled with metal. The resulting layer containing metal-filled lines residing in a dielectric is referred to as a metallization layer.

A long-standing objective in the advancement of IC technology has been the scaling down of IC dimensions. Such scaling-down of IC dimensions is critical to obtaining higher speed performance of ICs. An increase in IC performance is normally accompanied by a decrease in device area and/or an increase in device density. An increase in device density requires a decrease in via and trench dimensions (widths) used to form the interconnects. However, as feature dimensions on wafers decrease, negative consequences can come to bear. For example, reduced-size features may result in less reliable interconnects.

A conventional copper fill to produce interconnects can result in voids, particularly in features having a size of less than 30 nm. As one example of a type of void formed using conventional copper deposition, the opening of the feature may pinch off. Other types of voids can also result from using conventional copper fill process in small features. Such voids and other intrinsic properties of a deposit formed using conventional copper fill techniques can increase the resistance of the interconnect, thereby slowing down electrical performance of the device and reducing the reliability of the copper interconnect.

A further result of the ever-decreasing scaling down of interconnects is electromigration failure. Electromigration redistributes the copper in the interconnect and creates extrusions that can expand into the dielectric space. Generally, electromigration occurs when the metal atoms of conductive lines are subjected to high current density when the circuit is in operation. Metal atoms migrate in the direction of electron flow if the current density is high enough, thereby forming voids where metal ions have departed and forming extrusions consisting of metal material protruding outside the metal or dielectric barrier along the length of the metal interconnect. Voids will cause the copper interconnect to thin out and eventually separate completely, causing an open circuit. Moreover, extrusions can cause the copper metal to extend past the copper interconnect and into an adjacent copper line, thereby causing a short circuit.

With increasing miniaturization of integrated circuits, the likelihood of failure of interconnects due to electromigration increases with copper interconnects, because failure is caused by smaller voids. This necessitates a remedy to electromigration failures.

Once a void begins to develop in a metal line, the conducting metal becomes narrower at that point. Due to the reduction in conductor cross section, current density through the line increases at the narrowed location. As a result, the interconnect temperature increases due to Joule heating. As the temperature of the interconnect rises, the growth of the void accelerates, leading to a vicious cycle that eventually results in an open circuit.

Another drawback of copper interconnects is line resistance and via resistance in small features. For example, the 2003 ITRS projected for interconnects of 21 nm, resititivity was predicted to be 4 times larger than bulk resistivity. Sarvari, Reza, et al, “impact of size effects on the resistivity of copper wires and consequently the design and performance of metal interconnect networks.” Interconnect Technology Conference. 2005. Proceedings of the IEEE 2005 International. IEEE, 2005.

One way to address the drawbacks of copper metallization is to use a copper alloy or a metal other than copper, for example, W, Co, Ni, Mn, Sn, Au, Ag, Al, or alloys thereof. For example, Co is known to boost electromigration lifetimes as compared to Cu as a result of an improved interface and a higher melting point compared to Cu. A Co layer is commonly used in a Cu interconnect as a shunting layer and as an adhesion enhancement layer. Lane, M. W., E. G. Liniger, and J. R. Lloyd. “Relationship between interfacial adhesion and electromigration in Cu metallization.” Journal of Applied Physics 93.3 (2003): 1417-1421. Therefore, embodiments of the present disclosure are directed to an integration scheme for Co metallization to solve these and other problems.

### SUMMARY

This summary is provided to introduce a selection of concepts in a simplified form that are further described below in the Detailed Description. This summary is not intended to identify key features of the claimed subject matter, nor is it intended to be used as an aid in determining the scope of the claimed subject matter.

In accordance with one embodiment of the present disclosure, a method for depositing metal in a feature on a workpiece. The method includes forming a seed layer in a feature on a workpiece, wherein the seed layer includes a metal selected from the group consisting of cobalt and nickel; electrochemically depositing a first metallization layer on the seed layer, wherein electrochemically depositing the metallization layer includes using a plating electrolyte having a plating metal ion and a pH in the range of 6 to 13; and heat treating the workpiece after deposition of the first metallization layer.

In accordance with another embodiment of the present disclosure, a microfeature workpiece is provided. The workpiece includes a dielectric having a feature, wherein the critical dimension of the feature is less than 30 nm; and a bulk metallization layer in the feature having no detectable interface between an electrochemically deposited film and a seed film, wherein the bulk metallization layer includes cobalt or nickel.

In any of the embodiments described herein, the plating metal ion may be selected from the group consisting of cobalt, nickel, and copper.

In any of the embodiments described herein, the method may include depositing at least two features on a workpiece having two different sizes, wherein the seed layer fills the smallest feature, but does not fill the largest feature.

In any of the embodiments described herein, the method may include depositing at least two features on a workpiece having two different sizes, wherein the seed layer does not fill either feature.

In any of the embodiments described herein, the temperature for heat treating the workpiece may be in the temperature range of 150 degrees C. to 400 degrees C.

In any of the embodiments described herein, heat treating the workpiece may anneal the seed and first metallization layers.

In any of the embodiments described herein, heat treating the workpiece may reflow at least one of the seed and first metallization layers at least partially fill the feature.

In any of the embodiments described herein, the method may include plasma treating the seed layer using a hydrogen radical H*.

In any of the embodiments described herein, the method may include heat treating the seed layer before depositing the first metallization layer.

In any of the embodiments described herein, heat treating the seed layer may be in the temperature range of 200 degrees C. to 400 degrees C.

In any of the embodiments described herein, heat treating the seed layer may anneal the seed layer.

In any of the embodiments described herein, heat treating the seed layer may reflow the seed layer to at least partially fill the feature.

In any of the embodiments described herein, the first metallization layer may be a conformal or superconformal conductive layer.

In any of the embodiments described herein, the first metallization layer may include an overburden.

In any of the embodiments described herein, the first metallization layer may fill the largest features without depositing an overburden on the workpiece. In any of the embodiments described herein, the method may include electrochemically depositing a second metallization layer on the first metallization layer.

In any of the embodiments described herein, the second metallization layer may be an overburden, a cap, a fill layer, a conformal conductive layer, or a superconformal conductive layer.

In any of the embodiments described herein, the second metallization layer may not be subjected to heat treatment.

In any of the embodiments described herein, the method may include CMP.

In any of the embodiments described herein, the method may include heat treating the workpiece after CMP.

In any of the embodiments described herein, the seed layer may have a sheet resistance selected from the group consisting of greater than about 10 Ohm/sq., greater than about 50 Ohm/sq., and greater than about 100 Ohm/sq.

In any of the embodiments described herein, the seed layer may be deposited by a process selected from the group consisting of physical vapor deposition, chemical vapor deposition, atomic layer deposition, and electro-less deposition.

In any of the embodiments described herein, the workpiece may include an adhesion or barrier layer deposited in the feature prior to deposition of the seed layer.

In any of the embodiments described herein, the workpiece may include a cobalt seed layer deposited directly on a dielectric layer.

In any of the embodiments described herein, the critical dimension of the smallest feature may be less than 30 nm

In any of the embodiments described herein, electrical contacts to the workpiece for making an electrical connection with the workpiece in the electrochemical deposition process may be at least partially immersed in the deposition electrolyte.

In any of the embodiments described herein, the electrical contacts may be selected from the group consisting of open contacts, unsealed contacts, embedded contacts, and shielded contacts.

In any of the embodiments described herein, the first metallization layer may be deposited over the entire surface of the seed layer.

### DESCRIPTION OF THE DRAWINGS

The foregoing aspects and many of the attendant advantages of this disclosure will become more readily appreciated as the same become better understood by reference to the following detailed description, when taken in conjunction with the accompanying drawings, wherein:

FIGS. 1A-1F are a series of schematic illustrations of a method of forming a cobalt interconnect in accordance with one embodiment of the present disclosure;

FIGS. 2A-2G are a series of schematic illustrations of a method of forming a cobalt interconnect in accordance with another embodiment of the present disclosure;

FIGS. 3A-3F are a series of schematic illustrations of a method of forming a cobalt interconnect in accordance with another embodiment of the present disclosure;

FIGS. 4-6 are various tools for manufacturing workpieces according to methods described herein;

FIGS. 7A-7C are a series of schematic illustrations of a method of removing oxides and/or other contaminants from a seed layer in accordance with embodiments of the present disclosure;

FIG. 8 schematically illustrates a hydrogen ion plasma chamber for use with methods in accordance with embodiments of the present disclosure;

FIG. 9 schematically illustrates an electrochemical deposition plating tool for use with methods in accordance with another embodiment of the present disclosure;

FIGS. 10A and 10B are schematic illustrations depicting exemplary workpieces in accordance with embodiments of the present disclosure; and

FIGS. 11-21 are a series of flow diagrams depicting exemplary processes in accordance with embodiments of the present disclosure.

### DETAILED DESCRIPTION

The present disclosure relates to methods and integration for non-copper metallization layers, such as cobalt (Co) and nickel (Ni), in features (such as trenches and vias, particularly in Damascene applications) of a microelectronic workpiece.

Embodiments of the present disclosure are directed to workpieces, such as semiconductor wafers, devices or processing assemblies for processing workpieces, and methods of processing the same. The terms “workpiece,” “wafer,” and “semiconductor wafer” means any flat media or article, including semiconductor wafers and other substrates or wafers, glass, mask, and optical or memory media, MEMS substrates, or any other workpiece having micro-electric, micro-mechanical, or microelectro-mechanical devices.

Methods described herein are to be used for metal or metal alloy deposition in features of workpieces, including trenches and vias. In one embodiment of the present disclosure, the process may be used in small features, for example, features having a feature critical dimension of less than 50 nm. However, the processes described herein are applicable to any feature size. The dimension sizes discussed in the present application may be post-etching feature dimensions at the top opening of the feature. In one embodiment of the present disclosure, Damascene features may have a minimum dimension size of less than 50 nm. In another embodiment, Damascene features may have a minimum dimension size of less than 40 nm. In another embodiment, Damascene features may have a minimum dimension size of less than 30 nm.

The processes described herein may be applied to various forms of cobalt, nickel, alloys, for example, in Damascene applications. Processes described herein may also be modified for metal or metal alloy deposition in high aspect ratio features, for example, vias in through silicon via (TSV) features.

The descriptive terms “micro-feature workpiece” and “workpiece” as used herein may include all structures and layers previously deposited and formed at a given point in the processing, and is not limited to just those structures and layers as depicted in the figures. For example, larger features may be present on the workpieces in accordance with standard semiconductor procedure and manufacture.

Although generally described as metal deposition in the present application, the term “metal” also contemplates metal alloys and co-deposited metals. Such metals, metal alloys, and co-deposited metals may be used to form seed layers or to fully or partially fill the feature. As a non-limiting example in co-deposited metals and metal alloys, the alloy composition ratio may be in the range of about 0.5% to about 6% secondary alloy metal.

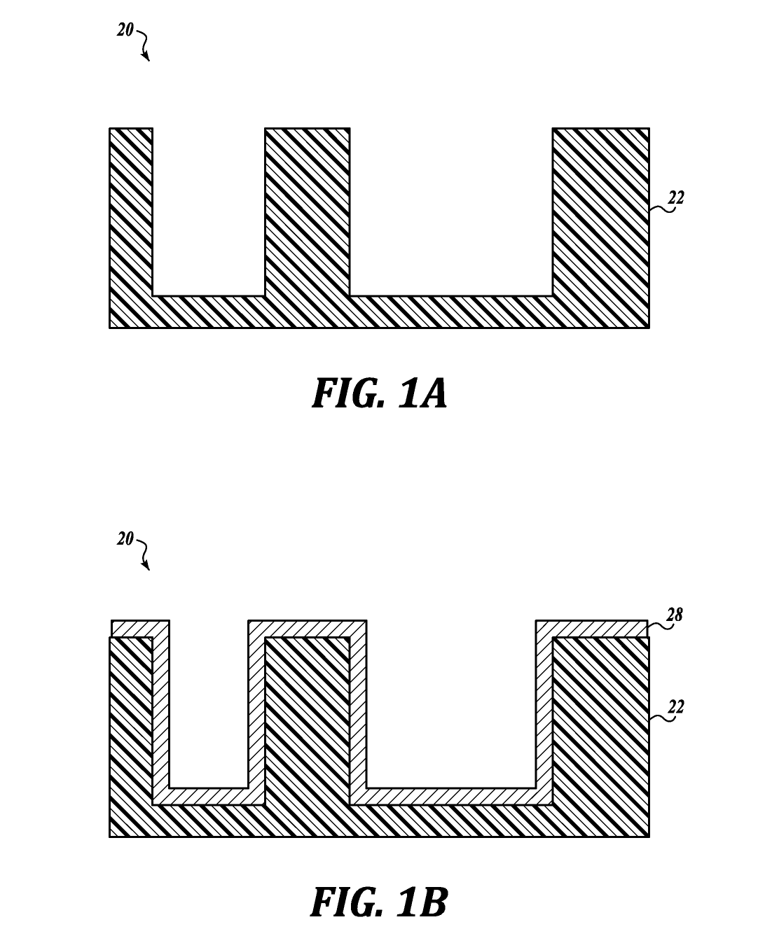

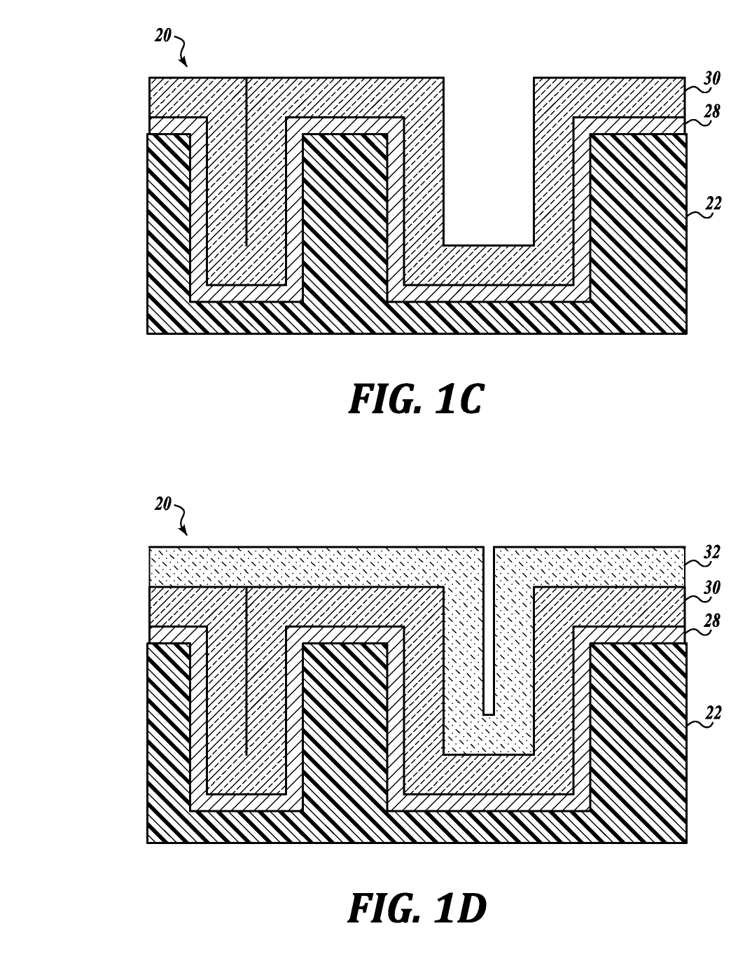

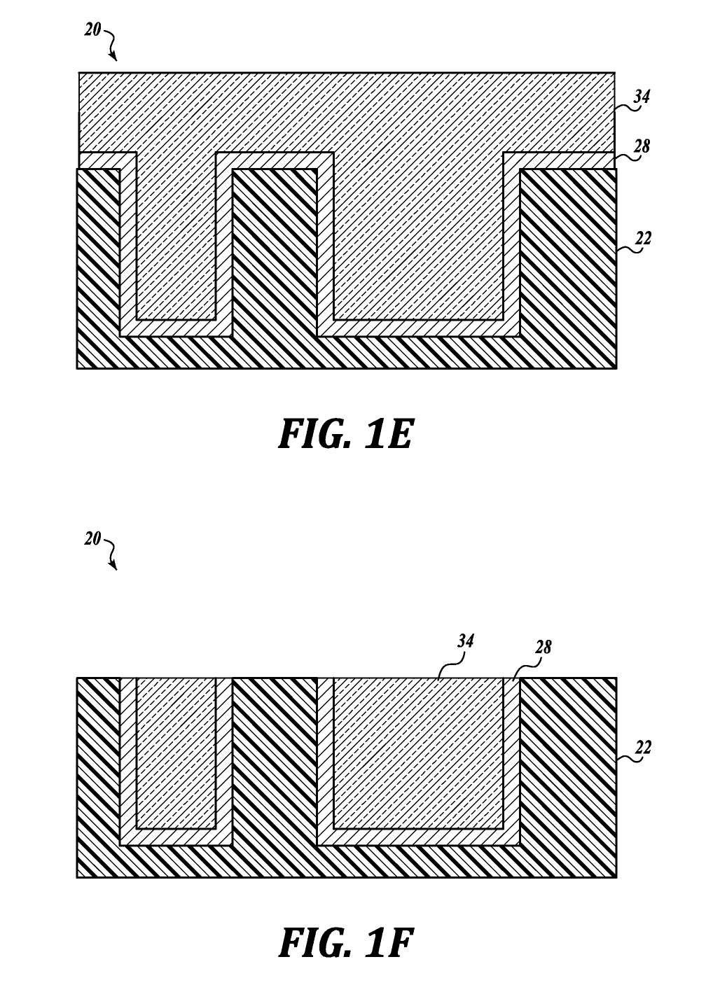

With reference to FIGS. 1A-1F, an integration scheme for filling one or more features using cobalt and forming exemplary cobalt interconnects will now be described. As a non-limiting example, the series of layers in a cobalt interconnect 20 typically include a dielectric layer 22 (see FIG. 1A), an optional adhesion layer 28 (see FIG. 1B), a seed layer 30 (see FIG. 1C), and a metallization layer 32 (see FIG. 1D). The integration scheme is illustrated for a first small feature and a second larger feature. As seen in FIG. 1C, the integration scheme includes depositing a thin CVD Co seed layer 30 in both the first and second features.

Referring to FIG. 1B, fabrication of the metal interconnect may include deposition of an optional adhesion layer 28 on the dielectric material Suitable adhesion layers include, for example, titanium (Ti), tantalum (Ta), titanium nitride (TiN), tantalum nitride (TaN), etc. As a non-limiting example, the adhesion layer may be a TiN layer formed by a CVD or an ALD process. In some application, an adhesion layer may not be required.

Referring to FIG. 1C, a seed layer 30 is deposited on the adhesion layer 28, or directly on the dielectric layer 22 if there is no adhesion layer. In accordance with embodiments of the present disclosure, the seed layer is, for example, formed from Co or Ni by a CVD process. Although commonly formed by a CVD process, the seed layers may also be formed by using other deposition techniques, such as ALD, PVD, or electroless deposition. The seed layer 30 may also be a stack film including a seed layer and a liner layer (not shown).

In the illustrated embodiment, the seed layer 30 fills the smaller feature, but does not fill the larger feature. As can be seen in FIG. 1C, the thickness of the seed layer may be equal to or greater than the ½ pitch of the smaller feature on the workpiece 20. In the illustrated embodiment, a seam is formed in the smaller feature where the two sides of the conformal seed layer 30 come together. The seed layer may have a film thickness in the range of about 5 nm to about 50 nm.

In another embodiment of the present disclosure, the Co seed layer may be thin enough to leave all features open and not filling even the smallest features on the workpiece. In another embodiment of the present disclosure, the Co seed layer may fill all the features (large and small) on the workpiece.

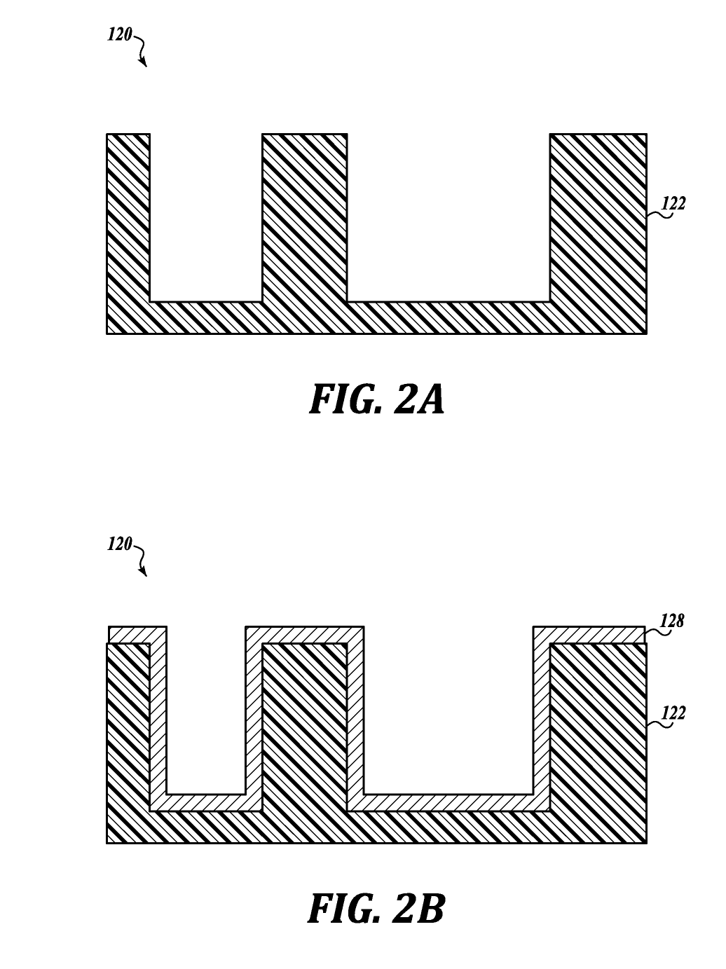

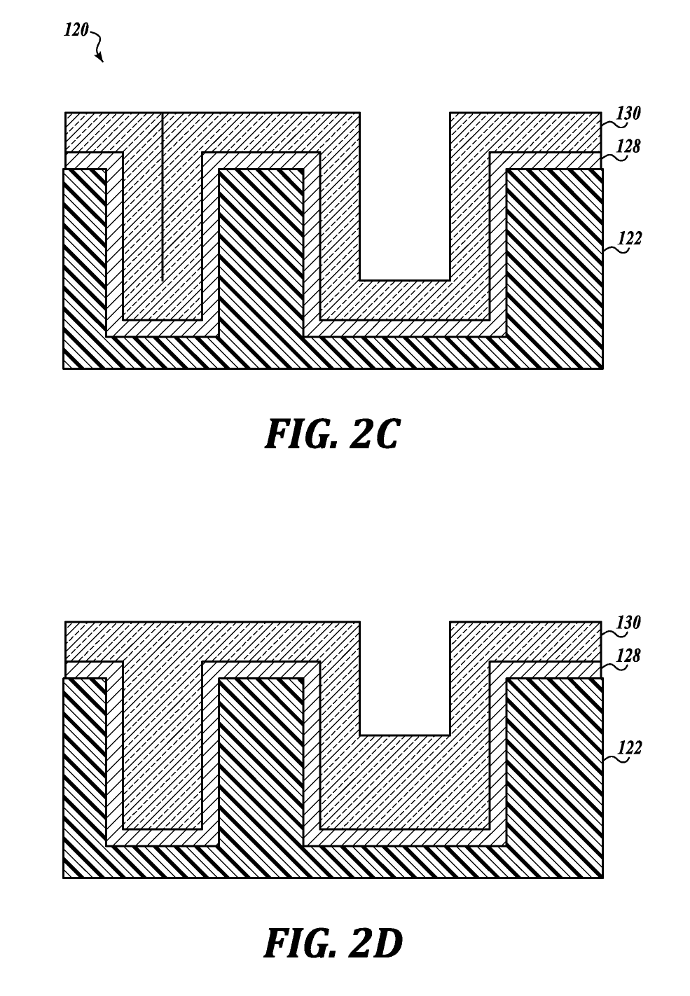

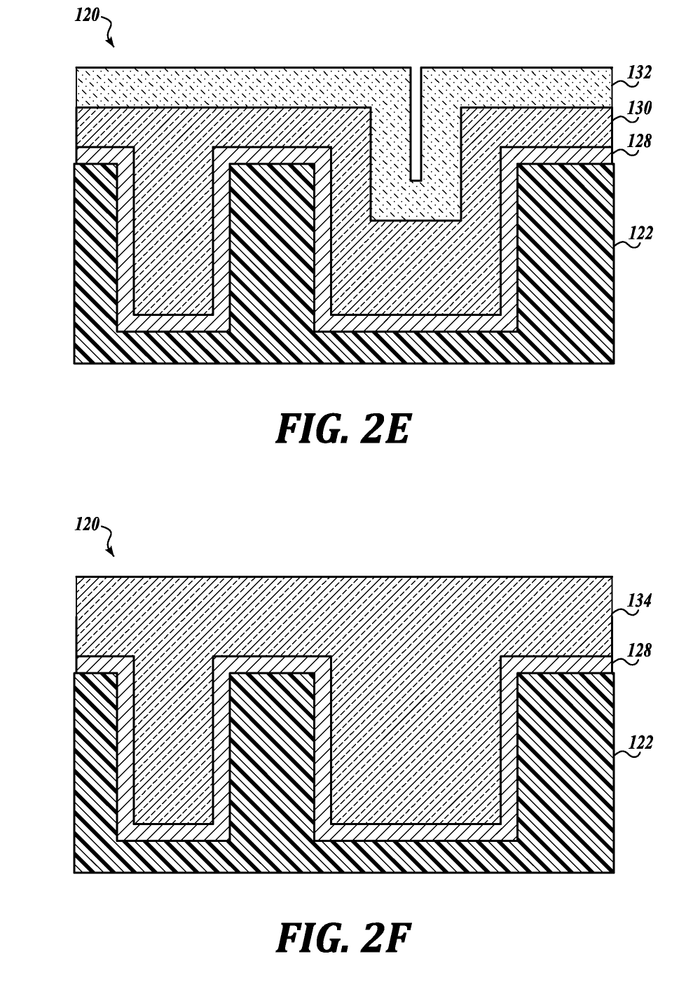

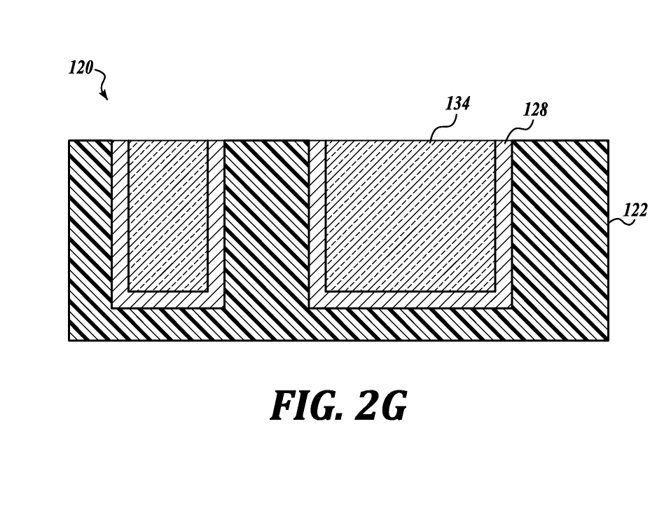

In one embodiment of the present disclosure, the workpiece 20 may be optionally annealed immediately following the seed layer 30 deposition process, as described in greater detail below (see FIGS. 2C and 2D). Such annealing may be advantageous for healing the seam, sealing micro-voids, stabilizing the film, densifying the film, lowering the resistivity of the film, and promoting crystal growth. In the present embodiment the seed layer 30 is not annealed. After deposition of the seed layer, an ECD Co layer is deposited, as seen in FIG. 1D. The ECD Co layer may have a film thickness in the range of about 50 nm and about 500 nm.

The ECD Co layer may be a conformal or super-conformal layer. In one non-limiting example, the ECD Co layer is deposited using an alkaline chemistry including a very dilute cobalt ethylenediamine (EDA) complex. ECD cobalt seed may also be deposited using other cobalt complexes, such as citrate, tartrate, glycine, ethylenediaminetetraacetic acid (EDTA), urea, etc., and may be deposited in a pH range of about 2 to about 11, about 3 to about 10, about 4 to about 10, or in a pH range of about 6 to about 10. In one embodiment of the present disclosure, the cobalt ECD alkaline chemistry may have a mildly acidic, neutral, or alkaline pH, for example in the range of about 6.5 to 8.3. In addition, the cobalt electrolyte may include a source of cobalt ions, such as cobalt chloride or cobalt sulfate, and a complexing agent, such as glycine or EDA.

In another non-limiting example, the electrolyte may include one or more components, such as organic additives, to achieve super-conformal fill.

In some exemplary embodiments of the present disclosure, deposition current density for ECD can range from 1 mA/cm² to 6 mA/cm² for dilute chemistry or from 1 mA/cm2 to 30 mA/cm2 for more concentrated chemistry. The waveform for applied current during deposition can be either direct current or pulsed current. Temperature during ECD can range between 15 to 40 degrees Celsius.

Instead of ECD Co layer, an ECD layer may be an ECD Cu layer.

As seen in comparing FIG. 1D with FIG. 1E, the workpiece 20 is then heat treated or annealed after deposition of the ECD Co layer. As mentioned above, annealing of the Co layer can provide one or more of the advantageous effects of healing the seed layer 30 seam, sealing micro-voids, stabilizing the film, densifying the film, lowering the resistivity of the film, and promoting crystal growth. As a not limiting example, resistivity may be in the range of about 8 to about 12 μΩ·cm post anneal. In some cases, the annealing layer may cause a reflow of the metal layers.

Annealing conditions for the ECD Co layer may be in a temperature range of 100 C to 400 C, and a pressure between 1 mTorr and 1 atm. In addition, a vacuum anneal is also within the scope of the present disclosure. The annealing environment may be hydrogen, a hydrogen/helium mix (e.g., 4% hydrogen, 96% helium), or a hydrogen/nitrogen mix (e.g., 4% hydrogen, 96% nitrogen). The time for the annealing process may be in the range of about 1 to about 60 minutes.

One advantageous effect of the methods described herein is single film filling the feature with no detectable interface between the electrochemically deposited film and the incoming “seed” film.

In the illustrated embodiment of FIGS. 1A-1F, the ECD Co process completely fills all features (small and large) leaving an overburden on the field of up to 5000 Angstroms. The overburden thickness may be the total Co thickness (Co seed plus Co ECD thickness). Therefore, the post plating anneal process in FIG. 1E anneals the overburden metal in addition to the metal filling the feature.

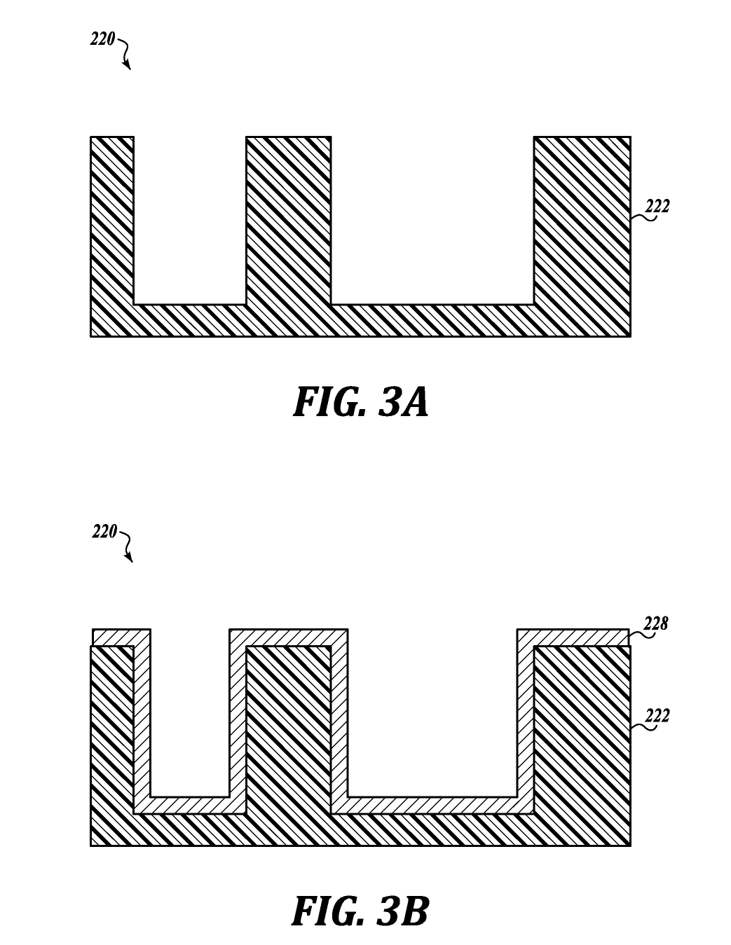

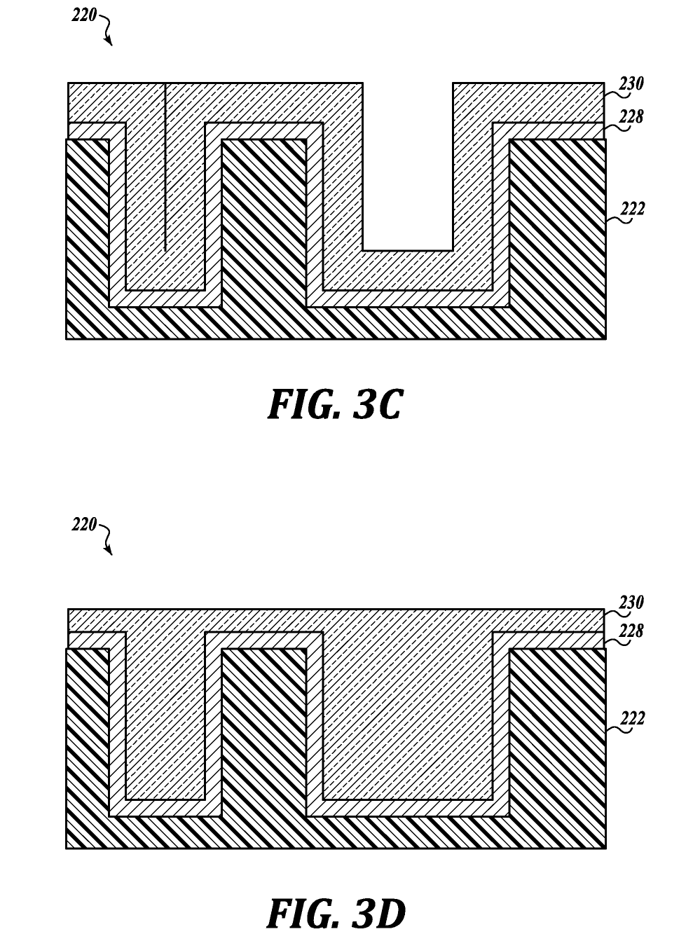

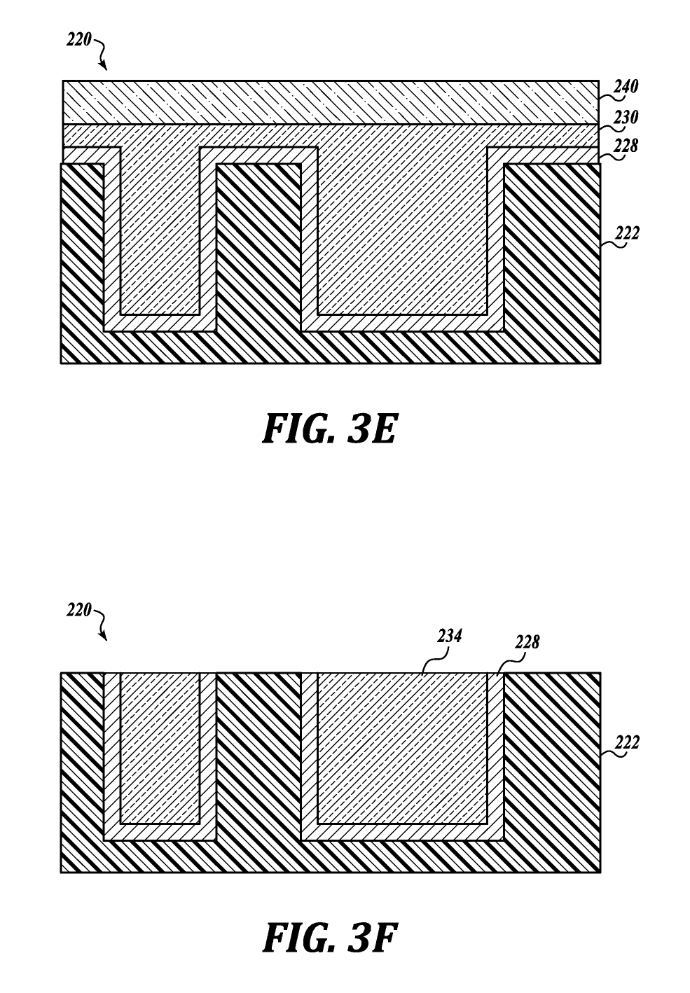

In another embodiment of the present disclosure, the ECD plating process overburden may be deposited after ECD Co deposition and annealing processes, such that the overburden is not subjected to the annealing step, as described below with reference to FIGS. 3E.

Subsequent conformal ECD Co layers may be deposited before or after the heat treatment.

Referring to FIG. 1F, the workpiece is then subjected to a chemical-mechanical planarization CMP process to reduce the overburden.

In accordance with embodiments of the present disclosure, the processes described herein may include a post-CMP anneal to promote crystal growth, to stabilize and lower the resistivity of the films, and to seal any remaining microvoids and seams.

In accordance with another embodiment of the present disclosure, a Co integration scheme is shown in FIGS. 2A-2G. In the scenario of FIGS. 2A-2G, Co integration is substantially similar to the method described with reference to FIGS. 1A-1F, except for differences in annealing processes relating to the seed layer. In the process of FIGS. 2A-2G, the Co seed is annealed to lower sheet resistance prior to ECD Co deposition (see FIG. 2D). After annealing, the seed layer thickness may be in the range of about 5 nm to about 35 nm.

In some cases, the annealing of the seed layer may cause a reflow of the seed layer. In other cases, the seed anneal may be performed without reflowing the seed layer. In addition, seam healing may occur during the annealing step. As mentioned above, annealing of the Co layer can provide one or more of the advantageous effects of sealing micro-voids, stabilizing the film, densifying the film, lowering the resistivity of the film, and promoting crystal growth. As a not limiting example, resistivity may be in the range of about 8 to about 12 μΩ·cm post anneal.

Annealing conditions for the Co seed layer may be in a temperature range of 100 C to 400 C, and a pressure between 1 mTorr and 1 atm. In addition, a vacuum anneal is also within the scope of the present disclosure. The annealing environment may be hydrogen, a hydrogen/helium mix (e.g., 4% hydrogen, 96% helium), or a hydrogen/nitrogen mix (e.g., 4% hydrogen, 96% nitrogen).

In accordance with another embodiment of the present disclosure, a Co integration scheme includes at least two discrete ECD Co deposition steps, one for filling the feature and the other for the overburden, is shown in FIGS. 3A-3F. In the scenario of FIGS. 3A-3F, Co integration is substantially similar to the method described with reference to FIGS. 1A-1F, except for differences in annealing processes relating to the overburden. In this integration scheme, the ECD Co annealing step may take place after filling the feature, but before the overburden deposition step. In this method, the metallization layer is annealed (see FIG. 3D), but the overburden is not annealed (see FIG. 3E). Annealing tends to increase the stress in a film. Therefore, not annealing the overburden allows for a lower stress in the interconnect. Because the overburden is a sacrificial portion of the workpiece subjected to CMP, there is little negative effect on no anneal of the overburden.

In accordance with embodiments of the present disclosure, an ECD electrolyte for conformal or super-conformal fill or a conventional acidic ECD electrolyte for bottom up can be used for overburden deposition.

The thickness of the ECD Co metallization layer in the first step may be in the range of about 50 nm to about 100 nm. The thickness of the ECD Co metallization layer in the second (overburden) step may be in the range of about 100 nm to about 300 nm.

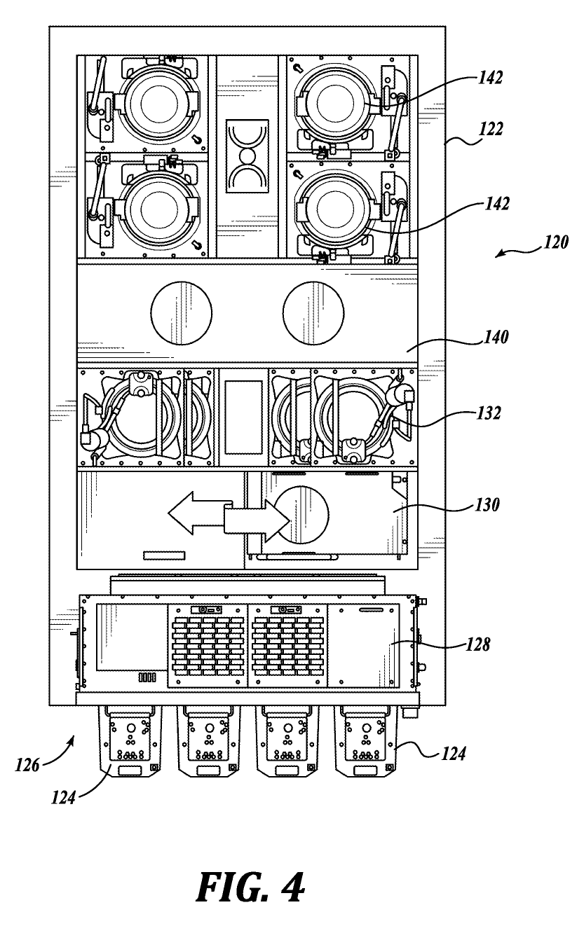

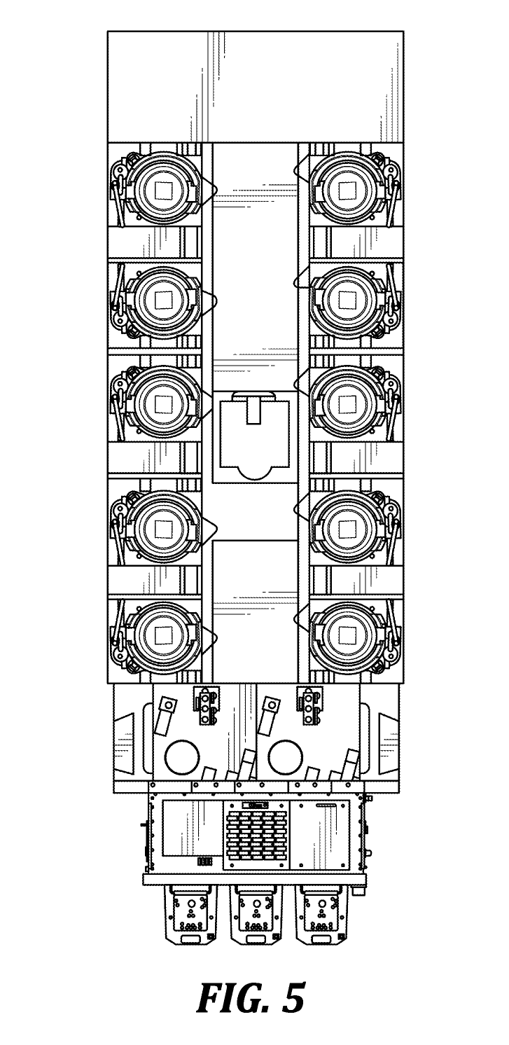

Various process steps in the methods described herein may be performed in the same processing tool or in different processing tools. Exemplary systems for processing workpieces are shown in FIGS. 4-6.

### Treatment with Hydrogen Plasma

Seed layers have a tendency to oxidize, and such oxidation may degrade subsequent metal deposition on the seed layer. In addition, an oxidized surface tends to increase defects and may degrade the reliability of the interconnect. A high temperature anneal of the seed layer in a reducing atmosphere tends to reduce such oxides. The oxides can be further reduced prior to metal deposition, for example, by plasma treatment either before, or during, or after the high-temperature anneal. In accordance with embodiments of the present disclosure, the anneal and plasma treatment steps may be performed in different chambers or in the same chamber, either simultaneously or in sequence.

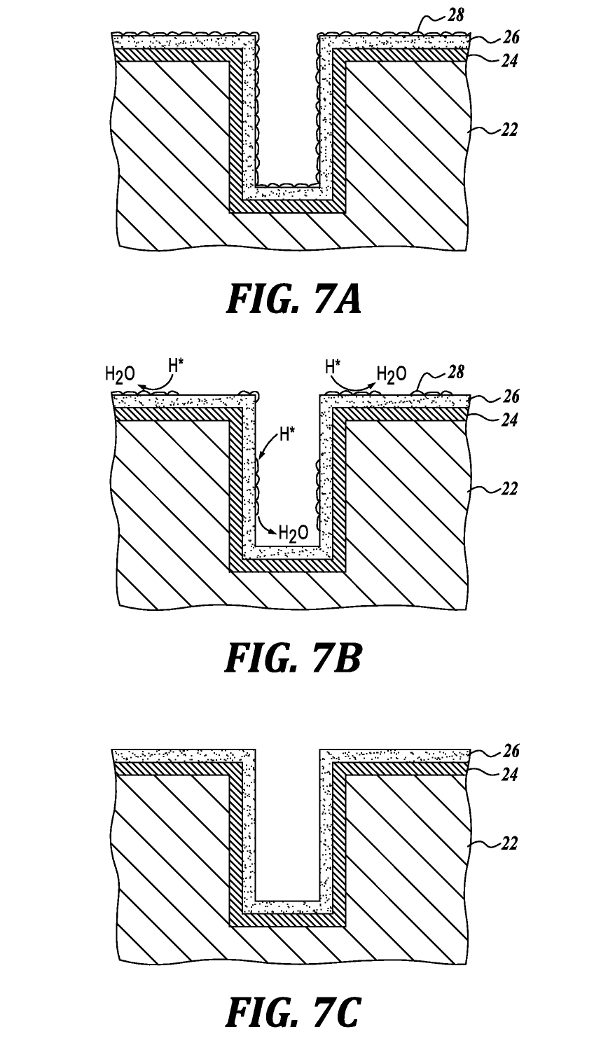

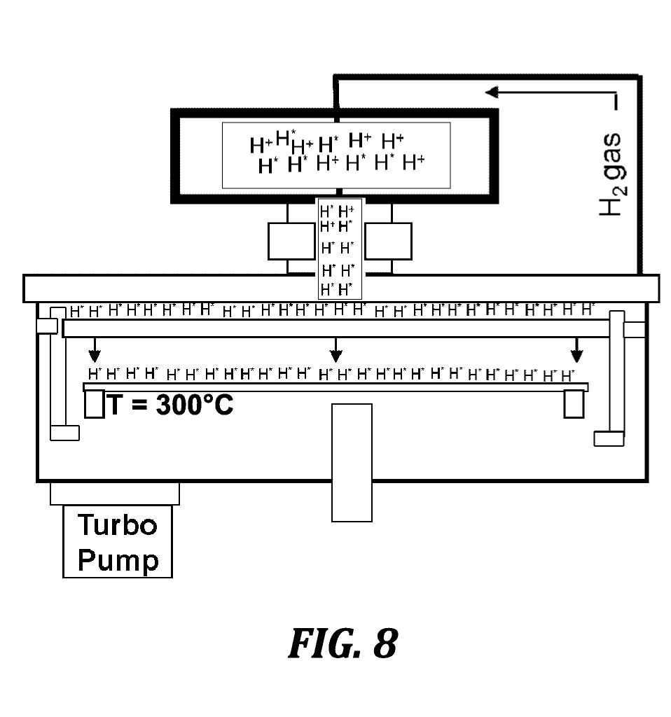

In accordance with embodiments of the present disclosure, surface treatment can be achieved using a low temperature surface treatment method so as to maintain the integrity and continuity of the deposited seed layer and minimize damage to the seed layer. Referring to FIG. 7A-7C, in one embodiment of the present disclosure, the seed layer is treated with hydrogen radicals H*. The hydrogen radicals H* is used to reduce metal oxides back to metal and covert the oxides to water. The hydrogen radical H* can also be used to clean contaminants from the seed layer surface, such as carbon.

In accordance with embodiments of the present disclosure, the hydrogen radicals H* may be generated using a plasma chamber, using a hot-filament radical source, or a combination of both. The hydrogen radicals H* can be used to uniformly reduce oxides and clean the seed layer surface in the feature.

Advantageous effects of hydrogen radical H* surface treatment in accordance with embodiments of the present disclosure include reduced agglomeration of the conductor layers and/or reduced changes to the intrinsic properties of the seed layer were typically caused by high temperature treatments in previously developed processes. Another advantageous effect of surface treatment includes enhances nucleation of the plated conductor as a result of the surface treatment to reduce oxygen and other contaminants.

After surface treatment by hydrogen radicals H*, a short processing window between surface treatment and electrochemical deposition, re-oxidation of the seed layer surface is significantly reduced. Accordingly, in some embodiments of the present disclosure, the time range between seed layer surface treatment and metallization layer deposition is less than 60 seconds. In other embodiments, the time range may be less than 30 seconds. In some embodiments, re-oxidation of the seed layer may be mitigated by storing the workpiece in a nitrogen environment (or another inert environment) before plasma surface treatment, after plasma surface treatment, or during other intervals in workpiece processing.

In some embodiments of the present disclosure, a wet process is used to reduce the oxide layer and further clean the surface of the seed, prior to plating. The wet process typically takes place in the plating bath, between wafer immersion in the bath and the initiation of plating. The wet process may be used with or without the plasma treatment described above. In some embodiments the wet clean process is performed without the preceding plasma treatment, and in those embodiments all oxides and surface contaminants are removed during the wet process. In other embodiments, a plasma treatment precedes the wet clean. In other non-limiting embodiments only plasma treatment is used and plating commences during immersion or immediately afterwards.

In comparison, a typical plating window after a seed deposition process is in the range of about 6-24 hours, generally considered by the industry to be an acceptable time period for plating interconnect metal on a seed layer. Moreover, cobalt seed layer surface treatment in accordance with the processing methods described herein may have the effect of improving adhesion, reducing defects, improving interconnect reliability, and other properties for subsequent cobalt metallization layers.

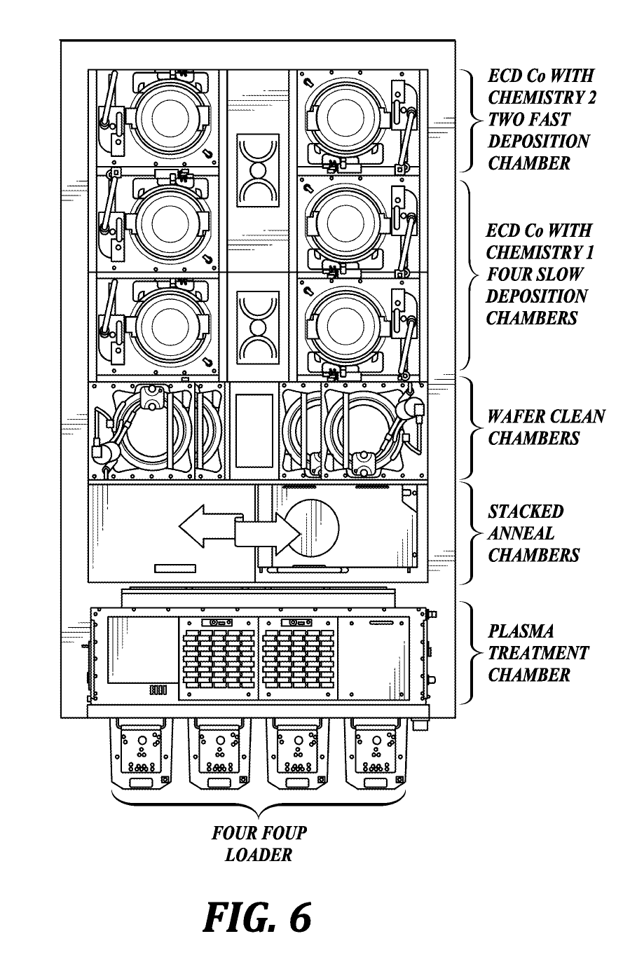

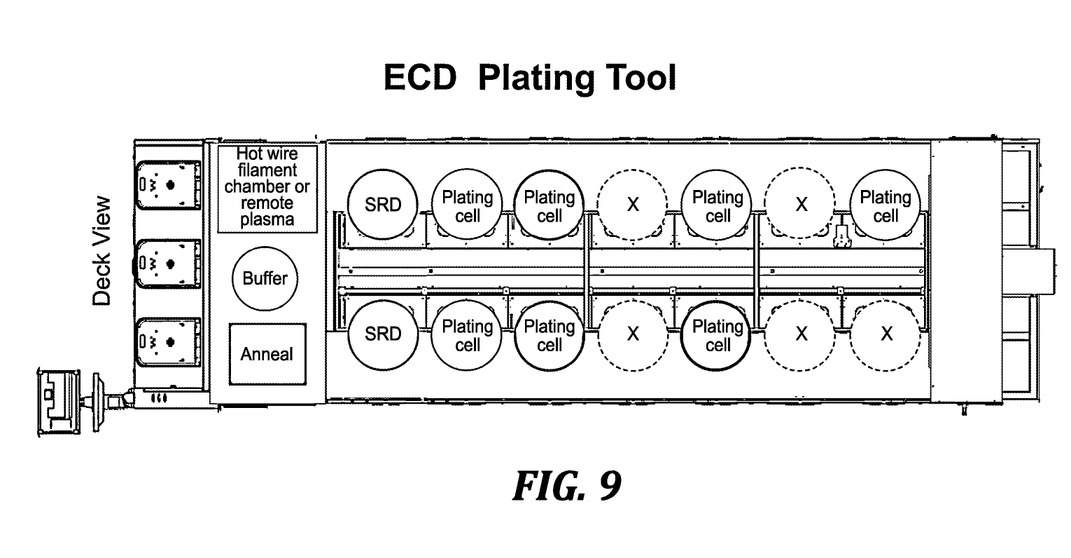

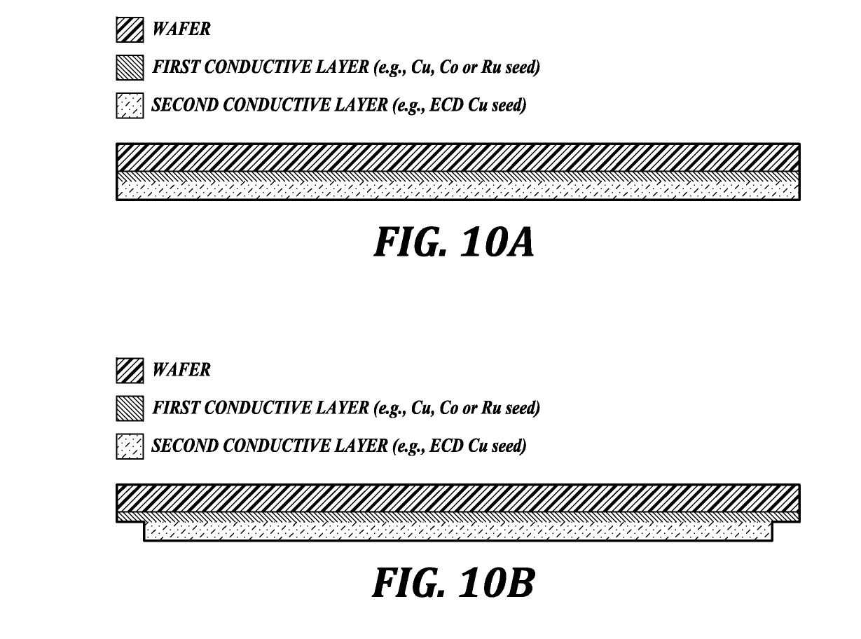

To achieve the short processing window, advances have been made to the plating tool. Referring to FIG. 9 an exemplary plating tool for use with methods described herein in shown. In the illustrated embodiment, a deck view of an exemplary RAIDER® plating tool manufactured by APPLIED Materials, Inc., is provided including several plating cells, spin-rinse-dry chambers, and a hydrogen radical H* generation chamber. By including the hydrogen radical H* generation chamber in the plating tool, the time range between seed layer surface treatment and metallization layer deposition can be 60 seconds or less. Another exemplary plating tool including a hydrogen radical H* generation chamber is shown in FIG. 6.

Another exemplary embodiment of an exemplary plating tool, commonly known as the MUSTANG® tool manufactured by APPLIED Materials, Inc., is shown in FIG. 4. The tool of FIG. 4 includes modules or subsystems within an enclosure 122. Wafer or substrate containers 124, such as FOUP (front opening unified pod) containers, may be docked at a load/unload station 126 at the front of the enclosure 122. Exemplary FOUPs may include a nitrogen environment to reduce metal layer oxidation during transfer. The subsystems used may vary with the specific manufacturing processes performed by the system 120. In the illustrated embodiment, the system 120 includes a front interface 128 which may provide temporary storage for wafers to be moved into or out of the system 120, as well as optionally providing other functions. As non-limiting examples, the system 120 may include an anneal module 130, a hydrogen radical H* generation chamber, a rinse/dry module 132, a ring module 140, and electroplating chambers 142, which may be sequentially arranged within the enclosure 122 behind the front interface 128. Robots move the wafers between the subsystems.

Another exemplary plating tool including a hydrogen radical H* generation chamber is shown in FIG. 6. The tool includes a plasma treatment chamber, stacked anneal chambers, wafer clean chambers, a plurality of ECD Co with Chemistry 1 deposition chambers, and a plurality of ECD Co with Chemistry 2 deposition chambers.

In some embodiments of the present disclosure, the tool may have an ambient air environment between chambers. In other embodiments, the tool may have a nitrogen environment in the enclosure between chambers to mitigate oxidation of the seed layer before plasma surface treatment, after plasma surface treatment, or during other intervals in workpiece processing.

In some embodiments of the present disclosure, the tool may include separate annealing and hydrogen radical H* generation chambers. In other embodiments of the present disclosure, the hydrogen radical H* generation may occur in the same chamber as is used for an annealing process. Although the same chamber may be used for both processes, the processes will occur separately in the workpiece manufacturing process, and not at the same time. To accommodate both processes, the chamber will have both hydrogen radical H* generation capabilities and annealing capabilities. In one embodiment, the chamber accommodates a temperature range from room temperature to 300° C. or room temperature to 400° C.

The combination of hydrogen radical H* generation and annealing in one processing chamber reduces that manufacturing site foot print of the tool and provides for annealing at high temperature and high vacuum, which may prove to be of benefit to the seed layer.

In some embodiments of the present disclosure, the metallization layer may be a copper metallization layer. In other embodiments of the present disclosure, the metallization layer may be a cobalt metallization layer. The metal options of the seed and metallization layers are described above. Embodiments of the present disclosure include, for example, a cobalt seed layer and a cobalt metallization layer. In these non-limiting examples, there is no distinguishable interface between seed and metallization layers upon reduction of the oxide layer as described herein. Other embodiments of the present disclosure include, for example, a cobalt seed layer and a copper metallization layer.

### Immersed Contacts

In accordance with other embodiments of the present disclosure, systems and methods for electrochemical deposition on a workpiece having high sheet resistance are provided. As feature size gets smaller and smaller, for example, less than 30 nm, the thin deposit seed layers tend to have very high sheet resistance. High sheet resistance is a problem when cobalt seed layers are used but is also seen with nickel or ruthenium seeds. High sheet resistance can create difficulties in electrochemical deposition (ECD) of subsequent metal layers, particularly when using “dry” electrical contacts. Embodiments of the present disclosure may apply to ECD seed, ECD seed plus (including an annealing step, as described above), ECD fill and cap, or any other ECD deposition process on a workpiece.

After a seed layer has been deposited according to one of the examples described above, the seed layer can be used as a cathode to deposit a metal layer onto the workpiece using an ECD process, with the electrode functioning as an anode for metal deposition. The ECD metal deposit may be an ECD seed, ECD fill, or ECD cap deposit.

ECD tools for use in manufacturing microelectronic devices often have a number of single-wafer electroplating chambers. A typical chamber includes a container for holding an ECD chemistry, an anode in the container to contact the chemistry, and a support mechanism having a contact assembly with electrical contacts that engage the seed layer. The electrical contacts are coupled to a power supply to apply a voltage to the seed layer. In operation, the surface of the workpiece is immersed in the chemistry such that the anode and the seed layer establish an electrical field that causes metal ions in a diffusion layer at the front surface of the workpiece to plate onto the seed layer.

One type of contact assembly is a “dry-contact” assembly having a plurality of electrical contacts that are sealed from the ECD chemistry. For example, U.S. Pat. No. 5,227,041, issued to Brogden et al., describes a dry contact ECD structure having a base member for immersion into an ECD chemistry, a seal ring positioned adjacent to an aperture in the base member, a plurality of contacts arranged in a circle around the seal ring, and a lid that attaches to the base member. In operation, a workpiece is placed in the base member so that the front face of the workpiece engages the contacts and the seal ring. When the front face of the workpiece is immersed in the ECD chemistry, the seal ring prevents the ECD chemistry from engaging the contacts inside the base member. Another type of contact assembly is a “wet-contact” assembly wherein the electrical contacts are permitted to contact the ECD chemistry. For example, U.S. Pat. No. 7,645,366, issued to Hanson et al., describes a wet-contact assembly that is immersed in the ECD chemistry.

When the sheet resistance of the seed layer is high, it is difficult to electrochemically deposit metal on the seed layer. In that regard, the sheet resistance of a very thin metal layer is inversely proportional to the thickness to the power of about 2 or more. For example, the sheet resistance of a copper film with thickness between 50 and 300 angstroms varies between 1.2 and 45 Ohms/sq. and is inversely proportional to the thickness of the film to the power of about 2.2. In one non-limiting example, the sheet resistance of a 10 angstrom ruthenium seed layer can be greater than 600 Ohms/sq. By comparison, the sheet resistance of a 50 angstrom ruthenium seed layer is less than 100 Ohms/sq.

Moreover, the sheet resistance of very thin films can also vary according to the deposition method, the post-deposition treatment, and the time between process steps. In that regard, metals deposited by CVD or ALD methods tend to have higher sheet resistance than metals deposited by PVD or electroplating means. This difference may be the result of one or more factors, such as higher impurity levels, different grain structures, and a reaction with atmospheric oxygen or moisture. This phenomenon is manifest for Co, Ru, Ni and many other metals. For example, CVD Co films were measured at higher than 1000 Ohms/sq., compared with a lower value for a PVD Co film of the same thickness.

Electrochemical deposition requires current conduction through the plated surface. The current supplies the electrons that reduce the ions of the plated metal to form the metal sheet or plated film. The deposition rate is proportional to the current. Thus, in order to accommodate and sustain a sufficient deposition rate, a high current must be supplied to the workpiece. The electric circuit in the system uses an anode, an electrolytic solution, and a cathode. The workpiece is typically the cathode and as current flows from the anode to the cathode, electrons are transferred from the cathode to the ions in the electrolyte to reduce those ions and deposit the film on the cathode. Depending on process conditions and the metal to be deposited, the current levels can vary, but during Co plating current may be as low as 0.1 to 0.5 A at the some points in the ECD process and as high as 10 A to 40 A during bulk deposition.

Electrical contact to the workpiece is achieved by means of a contact ring. Various designs for the contact ring exist in the art. There are four main categories of contact rings: wire (or open contact) contact ring, sealed contact ring, shielded contact ring, and embedded contact ring. In the case of unsealed contact rings, the electrical contacts between the workpiece and the ring are immersed in the electrolytic solution. In the case of the sealed ring, a seal separates the contacts from the solution. Thus, the electrical contacts in the unsealed rings (of all permutations) are “wet” whereas the electrical contacts of the sealed ring are “dry”.

A clear distinction between sealed and unsealed contacts is that, in the case of sealed contacts, no material is plated or deposited in the area that is sealed because the sealed area is not exposed to the electrolyte during electrochemical deposition process. An exemplary workpiece deposition scheme for “dry” contacts is provided in FIG. 10A. In that regard, a first conducting layer or seed layer is deposited on a substrate, and a second conducting layer or ECD seed layer is deposited on the first conducting layer. As can be seen in FIG. 10A, there is a void in the second conducting layer at the location of the contacts.

In contrast, unsealed contacts result in deposition or plating on the entire surface of the workpiece that is exposed to the electrolyte, including the contact area. An exemplary workpiece deposition scheme for “wet” contacts is provided in FIG. 10B. In that regard, a first conducting layer or seed layer is deposited on a substrate, and a second conducting layer or ECD seed layer is deposited on the seed layer. Unlike the workpiece in FIG. 10A, there is no void in the second conducting layer at the location of the contacts on the workpiece in FIG. 10B.

As discussed above, thin seed layers or seed layers made from metals other than copper tend to have high sheet resistance. Also, as explained above, the current passed to the cathode must pass through the seed layer. There are at least four different contact configurations for ECD, as follows. First, the contacts may be from a sealed ring, for which all current must flow through the thin seed and no deposition takes place outside the perimeter of the sealed ring. Refer to U.S. Pat. No. 5,227,041, issued to Brogden et al., for an exemplary sealed contact ring configuration.

Second, the contacts may be made from an unsealed ring, for which deposition takes place on the entire surface of the workpiece. Refer to U.S. Patent Publication No. 2013/0134035, to Harris, for an exemplary unsealed contact ring configuration.

Third, in another embodiment, the unsealed contact ring may be have “shielded” contacts to provide additional control in the system, for example, to control the flow of chemistry and/or the generation of air bubbles in the system.

Fourth, the contacts may be made from a sealed ring with embedded contacts. Embedded contacts are generally positioned inside the seal ring so that the outer perimeter edge of the workpiece remains dry. The metal contacts may either protrude from or be flush with the seal so that their tips are in contact with the workpiece and the chemistry solution inside the perimeter of the sealed ring. In this third configuration, no electrochemical deposition takes place on the dry area outside the perimeter of the sealed ring; however, the tip of the contacts are exposed to the electrolyte and to the film being electrochemically deposited while reaction takes place.

High sheet resistance creates high heat conditions on the workpiece. First principle calculations and simulations show that power dissipation through a very thin seed layer of thickness varying between 1 nm and 10 nm and sheet resistance varying from about 1000 Ohm/sq. to less than 10 Ohm/sq., could exceed 400 W. For example, a 1.5 nm thick film with resistivity of about 10 microOhms-cm and running at normal operating conditions of about 40 A would dissipate about 100 W. Accounting for the increase in resistivity associated with scattering of charge carriers and thin films properties, simulation shows that the heat dissipation of this film may exceed 400 W. Moreover, assuming that the contacts cover 50% of the workpiece circumference area, we calculate current density of about 20 MA/cm 2. This current density value exceeds the ampacity of thin films which, according to the International Technology Roadmap for Semiconductors (ITRS), is between 2 and 3 MA/cm 2, by a wide margin. Assuming adiabatic conditions we calculate that the heating rate of this film (dT/dt) would exceed 100 million K/s.

Although the film in question is not operating under adiabatic conditions, no known material can sustain such high heating rate and no known material can dissipate the heat generated at a sufficient rate to prevent rapid local heating. In experiments, the inventors found localized heating to be so great, that the dry part of a 5 nm Co film is capable of being damaged during electrochemical deposition, such as readily oxidizing or rapidly degrading. The thin film can oxidize under such heat, causing an open circuit and a stop to the electrochemical process. Therefore, it is difficult to deposit metal on a workpiece having a conductive layer having high sheet resistance using dry contacts, particularly with the current or current density is high, for example, exceeding 3 MA/cm2. High sheet resistance may be greater than 10, 50, or 100 Ohm/sq.

Embodiments of the present disclosure are directed to preventing such overheating. In cases in which the contacts are exposed to the electrolyte, the electrochemically deposited film creates a continuous film connecting the pins with the film deposited on the workpiece. For example, in the cases of an unsealed ring and an embedded sealed ring, electrochemical deposition of a film occurs at, near, and around the point of contact. As the electrochemically deposited film thickens during the electrochemical deposition process, the sheet resistance of the film rapidly decreases and the power dissipation quickly drops to near zero. Moreover, the liquid at the point of contact provides additional cooling and shielding from atmospheric oxygen, effectively preventing oxidation of the seed layer. Because heat dissipation quickly decreases, no significant heating of the seed layer takes place.

Moreover, the current profile can be adjusted to allow low current deposition at the initiation steps and higher current as the resistance drops. Because the heat dissipation is proportional to I 2, low initial current is an effective way to avoid seed damage. Current in such a current profile can vary in the range of about less than 0.5 A to about 80 A on a workpiece sizes of 300 or 450 mm.

### EXAMPLE 1

The following is an exemplary flow path for a workpiece in processing equipment for forming cobalt interconnects. Exemplary systems for processing workpieces are provided in FIGS. 4-6.

Wafer carrier is loaded onto the system containing wafers prepared with a thin conformal conductive seed film (e.g., CVD Co).

Wafer is removed from the carrier in an ambient or low oxygen environment.

(Optional) Wafer may be aligned to a common orientation (e.g., aligned to the notch).

(Optional) Wafer processed with either a thermal or plasma pretreatment to reduce oxides and/or anneal. (This step may also be performed in upstream equipment.)

Automation system transfers the wafer to sequential processing station. This station may be in an ambient or low oxygen environment.

Wafer is processed in a deposition cell using a wet electrical contact allowing deposition at the contact area and to the edge of the wafer during processing.

Wafer is rinsed and dried in the deposition chamber or another processing station.

Wafer is annealed.

(Optional) Wafer is processed in a deposition cell using a wet or dry contact for deposition of a subsequent ECD film. (Electroplating solution may be the same as that from previous deposition step.)

(Optional) Wafer is processed in a deposition cell using a wet or dry contact for deposition of overburden film. (Electroplating solution may be different from previous deposition step.)

(Optional) Wafer is rinsed and/or dried in the deposition chamber or another processing station.

(Optional) Wafer is rinsed and/or dried and/or bevel etches and/or backside cleaned in a processing station.

(Optional) Wafer is annealed.

Wafer is returned to a wafer carrier with a single film filling the pattern and an overburden with no detectable interface between the deposited film and the incoming “seed” film.

Wafer carrier may be removed and transferred to next manufacturing process.

Wafer is subjected to CMP.

(Optional) Wafer is annealed after CMP.

### EXAMPLE 2

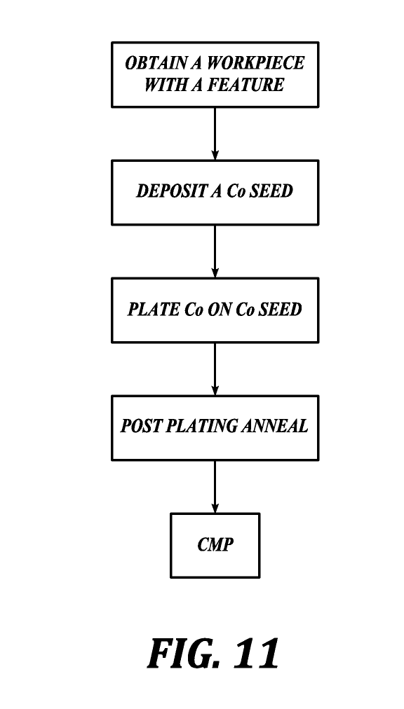

Referring to FIG. 11, an exemplary process for depositing a feature on a workpiece includes obtaining a workpiece with a feature, depositing a Co seed layer in the feature, electrochemically deposit a Co metallization layer on the Co seed layer, conducting a post-plating anneal, then subjecting the workpiece to CMP.

### EXAMPLE 3

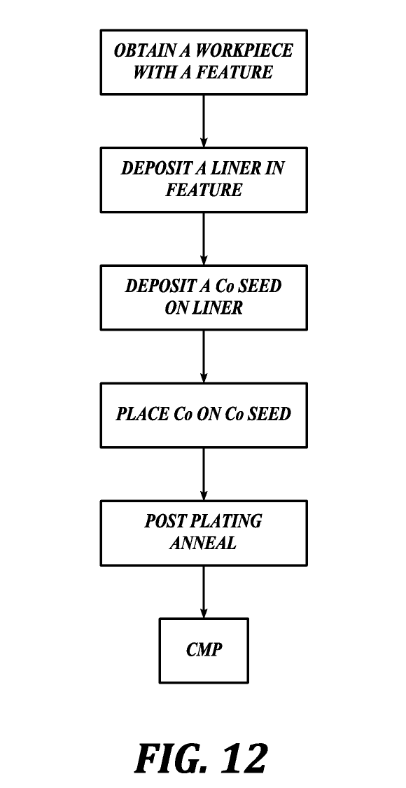

Referring to FIG. 12, an exemplary process is similar to the process in FIG. 11 and further includes a liner layer, such as an adhesion layer, deposited before the seed layer. The adhesion layer may be any suitable adhesion layer, such as a TiN or TaN layer.

### EXAMPLE 4

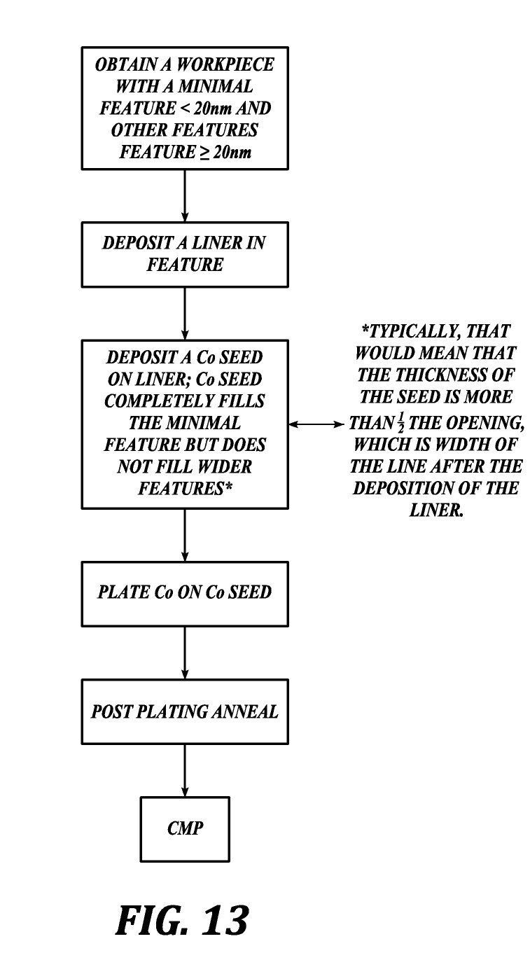

Referring to FIG. 13, an exemplary process is similar to one or more of the processes described above. The workpiece includes at least two features, one having a feature size of less than 20 nm and the other having a feature size of greater than or equal to 20 nm. When a Co seed is deposited, the Co Seed fills the smaller feature but does not fill the larger feature. When the seed fills the smaller feature the thickness of the seed may be more than ½ the opening size of the smaller feature. There may be a seam in the smaller feature after being filled by the seed layer.

### EXAMPLE 5

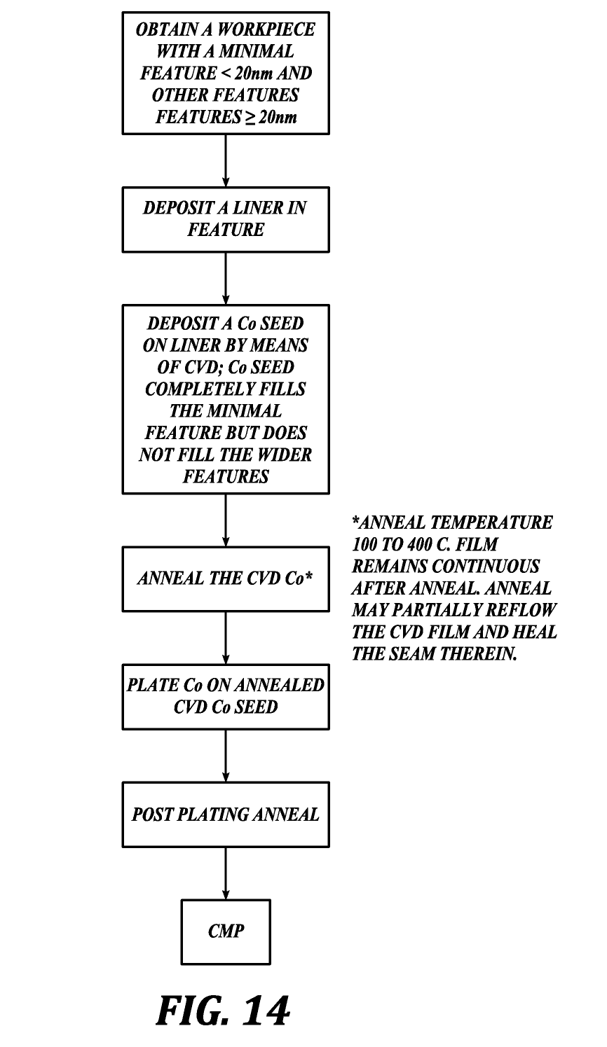

Referring to FIG. 14, an exemplary process is similar to one or more of the processes described above. After the Co seed layer is deposited, the Co seed layer is annealed. Annealing of the seed layer may be conducted in a temperature range of 100 to 400 degrees C. The annealing of the Co seed layer may partially reflow the seed layer and/or heal the seam therein. The Co seed anneal may be in addition to a second post plating anneal.

### EXAMPLE 6

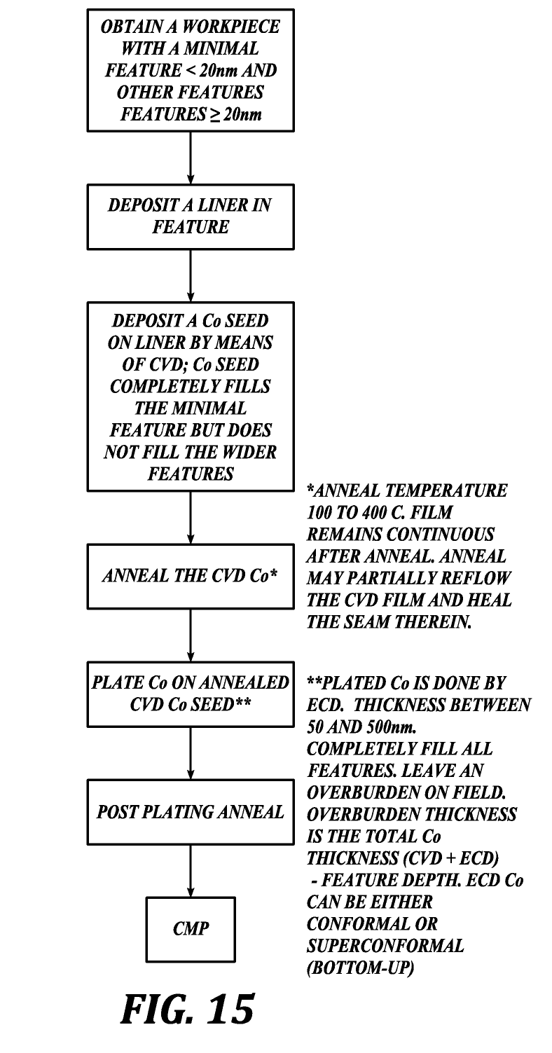

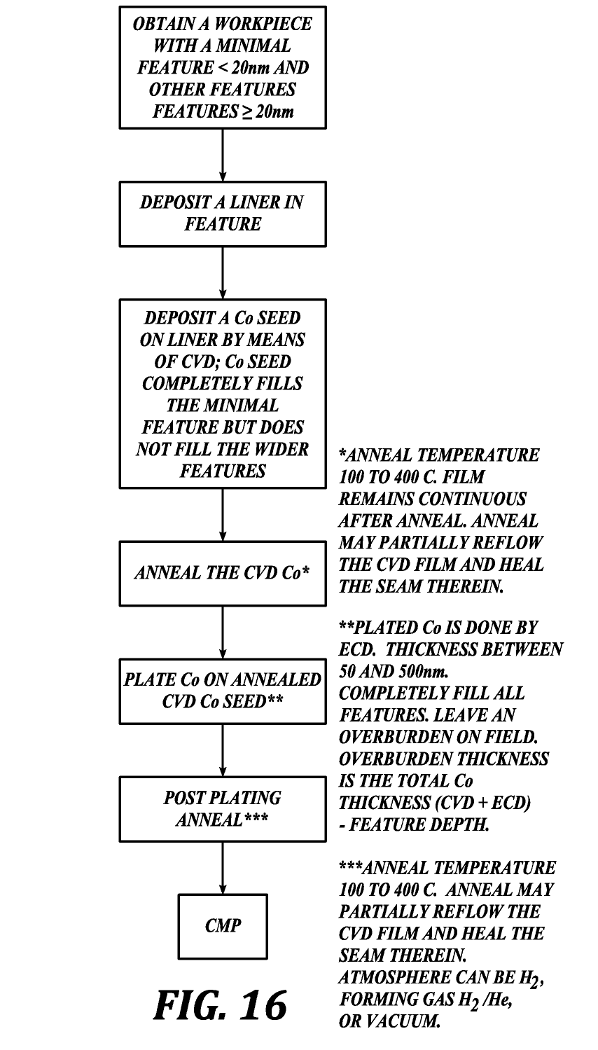

Referring to FIGS. 15 and 16, exemplary processes are similar to one or more of the processes described above. The plated Co is performed by an ECD process and has a thickness in the range of 50 nm to 500 nm. The ECD Co may be either conformal or super conformal fill. The ECD Co processes completely fills all features leaving an overburden on the field. The overburden thickness may be the total Co thickness (Co seed plus Co ECD thickness). Therefore, the post plating anneal process anneals the overburden metal in addition to the metal filling the feature.

### EXAMPLE 7

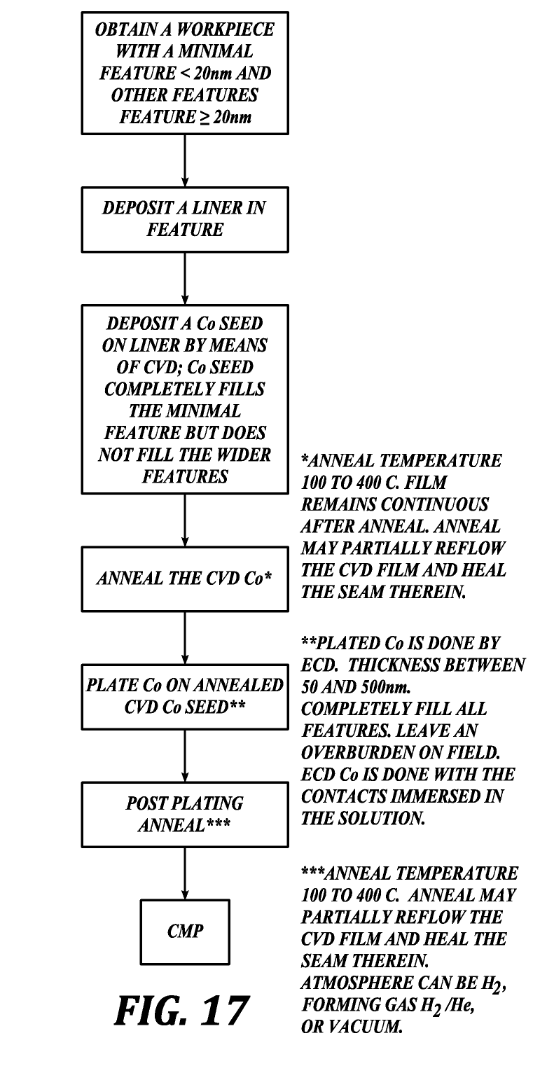

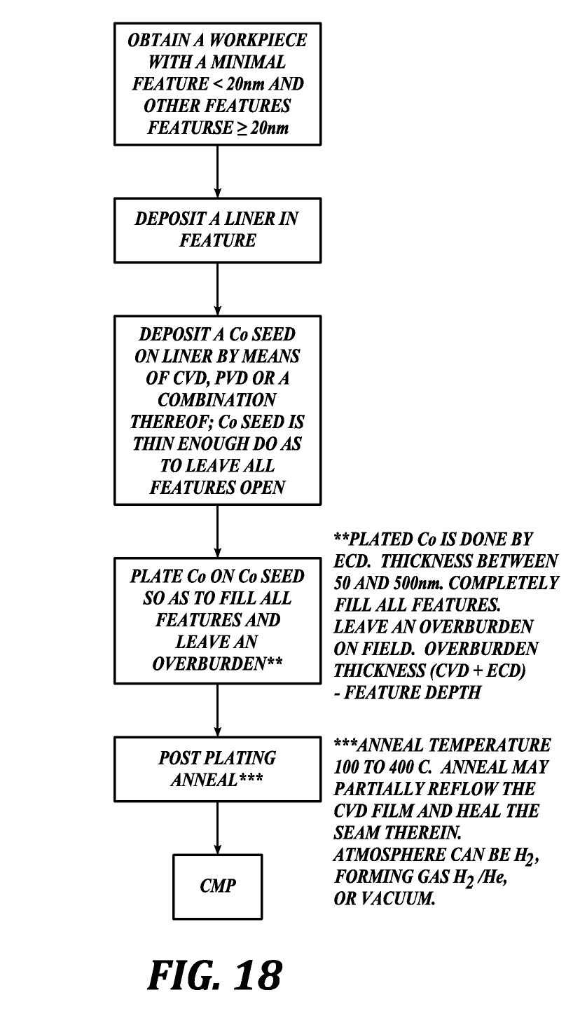

Referring to FIGS. 17 and 18, an exemplary process is similar to one or more of the processes described above. The ECD process is performed with contacts immersed in the electrolyte.

### EXAMPLE 8

Referring to FIG. 18, an exemplary process is similar to one or more of the processes described above. The Co seed is thin enough to leave all features open and not filling the smallest feature as described above in EXAMPLE 4.

### EXAMPLE 9

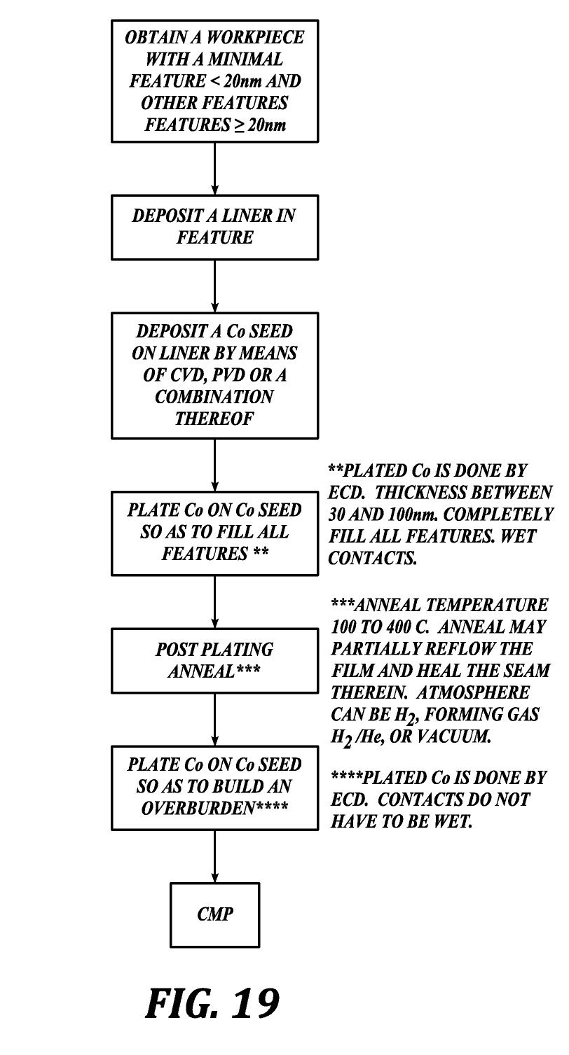

Referring to FIG. 19, an exemplary process is similar to one or more of the processes described above. The plated Co is performed by an ECD process and has a thickness in the range of 30 nm to 100 nm. The ECD Co may be either conformal or super conformal fill. The contacts may be immersed in the electrolyte. The ECD Co processes completely fills all features but does not leave an overburden on the field. After the ECD Co process, the workpiece is annealed. After annealing, an overburden is plated on the annealed ECD Co layer. For plating the overburden, the contacts may not need to be immersed in the electrolyte. Therefore, the overburden metal is not annealed, which may help to reduce stress in the workpiece. The workpiece is then subjected to CMP.

### EXAMPLE 10

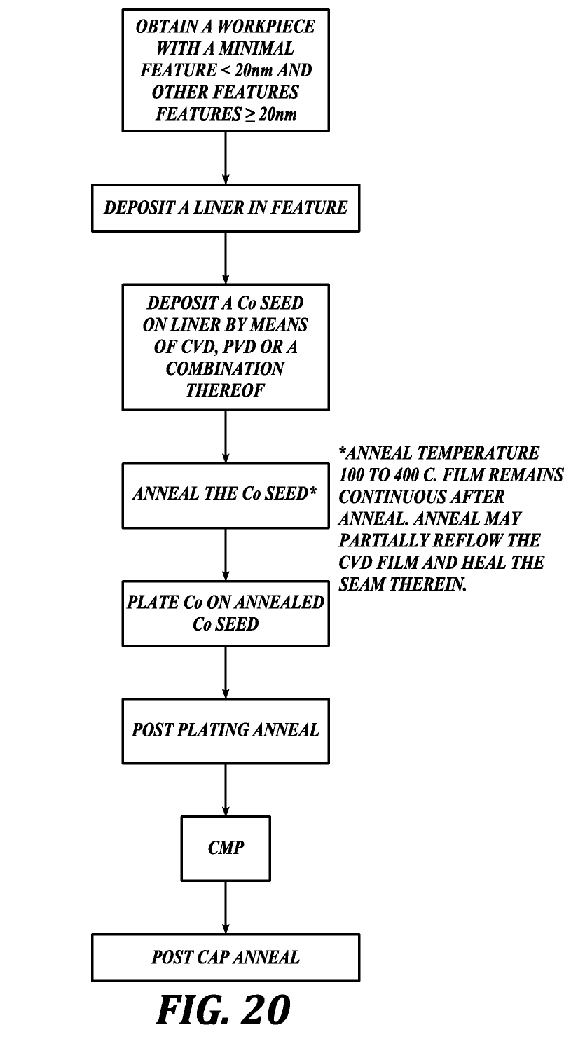

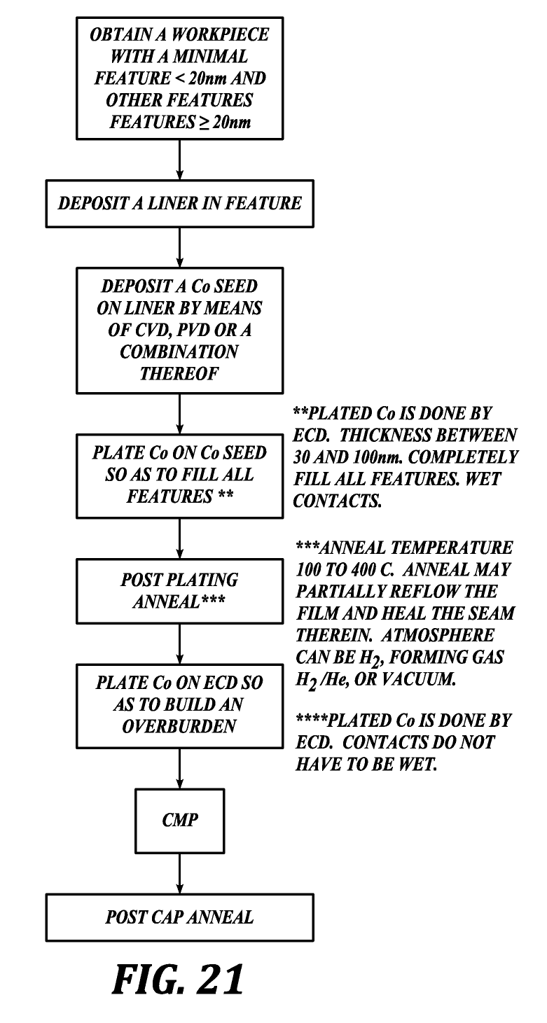

Referring to FIGS. 20 and 21, exemplary processes are similar to one or more of the processes described above. After CMP, the workpiece is subjected to post CMP anneal to promote crystal growth, to stabilize and lower the resistivity of the films, and to seal any remaining microvoids and seams. A post CMP anneal process is generally not used in larger features because of the tendency for protrusion. However, with small cobalt features, there is little risk of protrusion. FIG. 20 is directed to a process with an overburden plated during the ECD Co plating step prior to the post plating anneal step (see EXAMPLE 6). FIG. 21 is directed to a process with an overburden plated after the post plating anneal step (see EXAMPLE 9).

While illustrative embodiments have been illustrated and described, it will be appreciated that various changes can be made therein without departing from the spirit and scope of the disclosure.

The embodiments of the invention in which an exclusive property or privilege is claimed are defined as follows:

1. A method for depositing metal in a feature on a workpiece, the method comprising:
(a) forming a seed layer in a feature on a workpiece, wherein the seed layer includes a metal selected from the group consisting of cobalt and nickel;
(b) electrochemically depositing a first metallization layer on the seed layer, wherein electrochemically depositing the metallization layer includes using a plating electrolyte having a plating metal ion and a pH in the range of 6 to 13; and
(c) heat treating the workpiece after deposition of the first metallization layer.

2. The method of claim 1, wherein the plating metal ion is selected from the group consisting of cobalt, nickel, and copper.

3. The method of claim 1, further comprising depositing at least two features on a workpiece having two different sizes, wherein the seed layer fills the smallest feature, but does not fill the largest feature.

4. The method of claim 1, further comprising depositing at least two features on a workpiece having two different sizes, wherein the seed layer does not fill either feature.

5. The method of claim 1, wherein the temperature for heat treating the workpiece is in the temperature range of 150 degrees C. to 400 degrees C.

6. The method of claim 1, wherein heat treating the workpiece anneals the seed and first metallization layers.

7. The method of claim 1, wherein heat treating the workpiece reflows at least one of the seed and first metallization layers at least partially fill the feature.

8. The method of claim 1, further comprising plasma treating the seed layer using a hydrogen radical H*.

9. The method of claim 1, further comprising heat treating the seed layer before depositing the first metallization layer.

10. The method of claim 9, wherein heat treating the seed layer is in the temperature range of 200 degrees C. to 400 degrees C.

11. The method of claim 9, wherein heat treating the seed layer anneals the seed layer.

12. The method of claim 9, wherein heat treating the seed layer reflows the seed layer to at least partially fill the feature.

13. The method of claim 1, wherein the first metallization layer is a conformal or superconformal conductive layer.

14. The method of claim 1, wherein the first metallization layer includes an overburden.

15. The method of claim 1, wherein the first metallization layer fills the largest features without depositing an overburden on the workpiece.

16. The method of claim 1, further comprising electrochemically depositing a second metallization layer on the first metallization layer.

17. The method of claim 16, wherein the second metallization layer is an overburden, a cap, a fill layer, a conformal conductive layer, or a superconformal conductive layer.

18. The method of claim 16, wherein the second metallization layer is not subjected to heat treatment.

19. The method of claim 1, further comprising CMP.

20. The method of claim 1, further comprising heat treating the workpiece after CMP.

21. The method of claim 1, wherein the seed layer has a sheet resistance selected from the group consisting of greater than about 10 Ohm/sq., greater than about 50 Ohm/sq., and greater than about 100 Ohm/sq.

22. The method of claim 1, wherein the seed layer is deposited by a process selected from the group consisting of physical vapor deposition, chemical vapor deposition, atomic layer deposition, and electro-less deposition.

23. The method of claim 1, wherein the workpiece includes an adhesion or barrier layer deposited in the feature prior to deposition of the seed layer.

24. The method of claim 1, wherein workpiece includes a cobalt seed layer deposited directly on a dielectric layer.

25. The method of claim 1, wherein the critical dimension of the smallest feature is less than 30 nm

26. The method of claim 1, wherein electrical contacts to the workpiece for making an electrical connection with the workpiece in the electrochemical deposition process are at least partially immersed in the deposition electrolyte.

27. The method of claim 26, wherein the electrical contacts are selected from the group consisting of open contacts, unsealed contacts, embedded contacts, and shielded contacts.

28. The method of claim 1, wherein the first metallization layer is deposited over the entire surface of the seed layer.

29. A microfeature workpiece, comprising:
a dielectric having a feature, wherein the critical dimension of the feature is less than 30 nm;
a bulk metallization layer in the feature having no detectable interface between an electrochemically deposited film and a seed film, wherein the bulk metallization layer includes cobalt or nickel.
